(19) United States
(12) Patent Application Publication
(10) Pub. No.: US 2018/0005954 A1
(43) Pub. Date: Jan. 4, 2018

(54) THROUGH-SILICON VIA WITH INSULATOR FILL

(71) Applicant: INTERNATIONAL BUSINESS MACHINES CORPORATION, Armonk, NY (US)

(72) Inventors: DAVID W. ABRAHAM, CROTON, NY (US); JOHN M. COTTE, NEW FAIRFIELD, CT (US); ISAAC LAUER, YORKTOWN HEIGHTS, NY (US)

(21) Appl. No.: 15/198,479

(22) Filed: Jun. 30, 2016

(51) Int. Cl. H01L 23/532; H01L 21/768; H01L 21/285; H01L 23/528; H01L 23/48

(52) U.S. Cl. CPC H01L 23/53285; H01L 23/528; H01L 23/481; H01L 21/2855; H01L 21/76877; H01L 21/76831; H01L 21/76898

(57) ABSTRACT

Embodiments are directed to a method of forming a conductive via. The method includes forming an opening in a substrate and forming a conductive material along sidewall regions of the opening, wherein the conductive material occupies a first portion of an area within the opening. The method further includes forming an insulating fill in a second portion of the area within the opening, wherein at least one surface of the conductive material and at least one surface of the insulating fill are substantially coplanar with a front surface of the substrate.

### GOVERNMENT LICENSE RIGHTS

The invention described in the present description was made with government support under government contract number H98230-13-D-0173 awarded by the National Security Agency. The government has certain rights in the invention.

### BACKGROUND

The present invention relates in general to forming interconnect vias in integrated circuits (ICs). More specifically, the present invention relates to improved systems, fabrication methodologies and resulting structures for through-silicon vias (TSVs) that utilize a high purity low-void conductive material, are planar at front and back surfaces of the host wafer to facilitate downstream IC fabrication processes, and can be fabricated over a wide range of via aspect-ratios.

### SUMMARY

Embodiments of the present invention are directed to a method of forming a conductive via. The method includes forming an opening in a substrate and forming a conductive material along sidewall regions of the opening, wherein the conductive material occupies a first portion of an area within the opening. The method further includes forming an insulating fill in a second portion of the area within the opening, wherein at least one surface of the conductive material and at least one surface of the insulating fill are substantially coplanar with a front surface of the substrate.

Embodiments of the present invention are further directed to a method of forming a conductive via. The method includes forming an opening in a substrate and forming a layer of superconducting material along sidewall regions of the opening, wherein the layer of superconducting material occupies a first portion of an area within the opening. The method further includes filling a second portion of the area within the opening with an insulating material, wherein the opening extends through the substrate from a front surface of the substrate to a back surface of the substrate, wherein at least one surface of the layer of superconducting material and at least one surface of the insulating fill are substantially coplanar with the front surface of the substrate, wherein at least one second surface of the layer of superconducting material is substantially coplanar with the back surface of the substrate, and wherein an electrical conducting path is provided from the at least one surface of the layer of superconducting material to the at least one second surface of the layer of superconducting material.

Embodiments of the present invention are further directed to a conductive via having an opening in a substrate and a conductive material along sidewall regions of the opening, wherein the conductive material occupies a first portion of an area within the opening. The conductive via further includes an insulating fill in a second portion of the area within the opening, wherein at least one surface of the conductive material and at least one surface of the insulating fill are substantially coplanar with a front surface of the substrate.

Additional features and advantages are realized through the techniques described herein. Other embodiments and aspects are described in detail herein. For a better understanding, refer to the description and to the drawings.

### BRIEF DESCRIPTION OF THE DRAWINGS

The subject matter which is regarded as the present invention is particularly pointed out and distinctly claimed in the claims at the conclusion of the specification. The foregoing and other features and advantages are apparent from the following detailed description taken in conjunction with the accompanying drawings in which:

FIG. 1 depicts a cross-sectional view of a completed via structure according to one or more embodiments of the present invention;

FIG. 2 depicts a cross-sectional view of another completed via structure according to one or more embodiments of the present invention;

FIG. 3 depicts a cross-sectional view of a semiconductor wafer after an initial via fabrication stage according to one or more embodiments;

FIG. 4 depicts a cross-sectional view of a semiconductor wafer after another via fabrication stage according to one or more embodiments;

FIG. 5 depicts a cross-sectional view of a semiconductor wafer after another via fabrication stage according to one or more embodiments;

FIG. 6 depicts a cross-sectional view of a semiconductor wafer after another via fabrication stage according to one or more embodiments;

FIG. 7 depicts a cross-sectional view of a semiconductor wafer after another via fabrication stage according to one or more embodiments;

FIG. 8 depicts a cross-sectional view of a semiconductor wafer after another via fabrication stage according to one or more embodiments;

FIG. 9 depicts a cross-sectional view of a semiconductor wafer after another via fabrication stage according to one or more embodiments;

FIG. 10 depicts a cross-sectional view of a semiconductor wafer after another via fabrication stage according to one or more embodiments;

FIG. 11 depicts a cross-sectional view of a semiconductor wafer after another via fabrication stage according to one or more embodiments;

FIG. 12 depicts a cross-sectional view of a semiconductor wafer after another via fabrication stage according to one or more embodiments;

FIG. 13 depicts a cross-sectional view of a semiconductor wafer after another via fabrication stage according to one or more embodiments;

FIG. 14 depicts a cross-sectional view of a semiconductor wafer after another via fabrication stage according to one or more embodiments;

FIG. 15 depicts a cross-sectional view of a semiconductor wafer after another via fabrication stage according to one or more embodiments; and

FIG. 16 depicts a flow diagram illustrating a via fabrication methodology according to one or more embodiments.

In the accompanying figures and following detailed description of the disclosed embodiments, the various elements illustrated in the figures are provided with three or four digit reference numbers. The leftmost digit(s) of each reference number corresponds to the figure in which its element is first illustrated.

### DETAILED DESCRIPTION

It is understood in advance that, although this description includes a detailed description of the formation and resulting structures for a specific type of via (i.e., a TSV), implementation of the teachings recited herein are not limited to a particular type of via or integrated IC architecture. Rather embodiments of the present invention are capable of being implemented in conjunction with any other type of via or IC architecture, now known or later developed.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” can be understood to include any integer number greater than or equal to one, i.e. one, two, three, four, etc. The terms “a plurality” can be understood to include any integer number greater than or equal to two, i.e. two, three, four, five, etc. The term “connection” can include both an indirect “connection” and a direct “connection.”

For the sake of brevity, conventional techniques related to semiconductor device and IC fabrication may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

By way of background, however, a more general description of the semiconductor device fabrication processes that can be utilized in implementing one or more embodiments of the present invention will now be provided. Although specific fabrication operations used in implementing one or more embodiments of the present invention can be individually known, the disclosed combination of operations and/or resulting structures of the present invention are unique. Thus, the unique combination of the operations described in connection with the fabrication of a via according to the present invention utilize a variety of individually known physical and chemical processes performed on a semiconductor (e.g., silicon) substrate, some of which are described in the following immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Fundamental to the above-described fabrication processes is semiconductor lithography, i.e., the formation of three-dimensional relief images or patterns on the semiconductor substrate for subsequent transfer of the pattern to the substrate. In semiconductor lithography, the patterns are a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Semiconductor devices are used in a variety of electronic and electro-optical applications. ICs are typically formed from various circuit configurations of semiconductor devices (e.g., transistors, capacitors, resistors, etc.) and conductive interconnect layers (known as metallization layers) formed on semiconductor wafers. Alternatively, semiconductor devices can be formed as monolithic devices, e.g., discrete devices. Semiconductor devices and conductive interconnect layers are formed on semiconductor wafers by depositing many types of thin films of material over the semiconductor wafers, patterning the thin films, doping selective regions of the semiconductor wafers, etc.

In contemporary semiconductor fabrication processes, a large number of semiconductor devices and conductive interconnect layers are fabricated in and on a single wafer. The conductive interconnect layers serve as a network of pathways that transport signals throughout an IC, thereby connecting circuit components of the IC into a functioning whole and to the outside world. Conductive interconnect layers vary in number and type depending on the complexity of the device. Interconnect layers are themselves interconnected by a network of holes (or vias) formed through the IC. For example, a through-silicon via (TSV) is an electrical contact that passes completely through the semiconductor wafer or die. In multilevel IC configurations, for example, a TSV can be used to form vertical interconnections between a semiconductor device located on one level of the IC and an interconnect layer located on another level of the IC. As IC feature sizes continue to decrease, the aspect ratio, (i.e., the ratio of height/depth to width) of features such as vias generally increases. With narrower, taller (i.e., higher-aspect-ratio) vias, the resistivity of the via must be kept sufficiently low. Otherwise, the via can fail, possibly causing failure of the entire IC. Fabricating intricate structures of conductive interconnect layers and vias within an increasingly smaller IC footprint is one of the most process-intensive and cost-sensitive portions of semiconductor IC fabrication.

In its simplest configuration, a TSV is formed by creating a hole or an opening through the semiconductor wafer at a desired location, and then filling the hole/opening with conductive material, thereby providing a solid metal contact that extends from a front side of the wafer to a back side of the wafer. There are several considerations in forming TSVs. For example, in order to be compatible with downstream processing techniques, the conductive metal fill of the via must be substantially planar with the front side of the wafer and the back side of the wafer. Additionally, in order to minimize downstream fabrication problems, it is necessary to completely fill the via with conductive material in a manner that leaves no voids, which is difficult to do using known via fabrication techniques. To facilitate filling of the via, relatively narrow (i.e., high-aspect-ratio) vias are often used because is it generally accepted that, using known via fabrication techniques, it is easier to completely fill a relatively narrow via than a relatively wide (i.e., low-aspect-ratio) via. Higher-aspect-ratio (i.e., taller) vias are also advantageous because they take up less wafer/chip space and cause less stress to the wafer/chip.

Known deposition techniques for filling a via opening/hole with conductive material require tradeoffs. For example, chemical vapor deposition (CVD) is considered to be compatible with depositing material within a narrow, high-aspect-ratio space. However, because the CVD deposited gas is a mixture of the desired conductive material and a carrier organic gas, the conductive material remaining after CVD is less pure than other deposition procedures, such as physical vapor deposition (PVD). PVD is a line-of-sight process in which a desired fill material (e.g., copper) is sputtered (or knocked) from a target into the via opening/hole. PVD and similar deposition techniques result in a very pure conductive material fill because only the material of interest is deposited in the via opening/hole. However, because PVD is a line-of-sight process, using PVD to create conductive material fill within a narrow, high-aspect-ratio via having perpendicular sidewalls is a challenge. For example, applying a line-of-sight deposition process in a narrow, low-aspect-ratio via opening/hole can result in the space between the via opening/hole sidewalls being filled before the bottom of the via opening/hole (due to the sticking coefficient at the upper edges of the sidewalls), which results in voids at the bottom of the via opening/hole and overfill at the top of the via opening/hole. The presence of voids in the via conductive material causes problems in downstream fabrication processes, and the overfilled conductive material requires additional post-deposition processing operations in order to planarize the overfill down to the wafer surface. Although using a relatively wide, low-aspect-ratio via would make the via more compatible with a line-of-sight deposition process, as previously noted, it is generally accepted that a relatively wide, low-aspect-ratio via is harder to completely fill with conductive material using known via and conductive material fill formation techniques.

Accordingly, it would be beneficial to provide systems, fabrication methodologies and resulting structures for TSVs that utilize high purity low-void conductive material, are planar with the front and back surfaces of the wafer, and are less dependent than known techniques on the aspect-ratio of the via.

Embodiments of the present invention provides improved systems, fabrication methodologies and resulting structures for TSVs that utilize a high purity low-void conductive material, are planar with front and back surfaces of the wafer to facilitate downstream IC fabrication processes, and can be fabricated over a wide range of via aspect-ratios. According to one or more embodiments, the via can be fabricated by forming an opening from a front surface to a back surface of a semiconductor substrate. The via is then partially filled with a conductive material. In one or more embodiments, the partial filling includes providing conductive material along some or all of the via sidewalls to form, in effect, a conductive material liner along the via sidewalls. In one or more embodiments, the conductive material liner extends along the via sidewalls from a front surface of the wafer to the back surface of the wafer, thereby providing an electrical conductance path through from a front wafer surface through the conductive liner to a back surface of the wafer. In one or more embodiments, the conductive liner is formed using a damascene process. In one or more embodiments, a line-of-sight deposition process such as PVD can be used to form the conductive liner, which results in a conductive liner having high purity and also allows a wide range of conductive materials. In one or more embodiments, the partially filled conductive material is a superconducting material. In one or more embodiments, after the partial fill the remaining space within the via is filled with insulator. The resulting conductive liner and insulator fill structure is then integrated by making contact to the top and bottom ground planes or to the signal carrying lines on each wafer surface.

The disclosed conductive material liner with insulator fill TSV structure is compatible with both high-aspect ratio (e.g., aspect ratios above about 4:1) and lower-aspect-ratio (e.g., aspect ratios between about 2:1 and about 4:1), particularly for embodiments wherein the conductive material liner is a superconducting material. The use of a superconducting material for the liner allows the desired via resistivity to be achieved with a relatively thin film of superconducting material. The use of an insulator fill eliminates voids in the via opening, and can be accomplished with relatively simple fabrication techniques. The conductive liner and the insulating fill each provide surfaces that are substantially coplanar with the front and back surfaces of the wafer, which is required for effective downstream wafer fabrication operations (e.g., operations that require the uniform deposition of a photoresist layer over the wafer). The disclosed conductive material liner with insulator fill TSV structure is particularly useful where the conductive material is a superconducting material and where the operating environment is cryogenic.

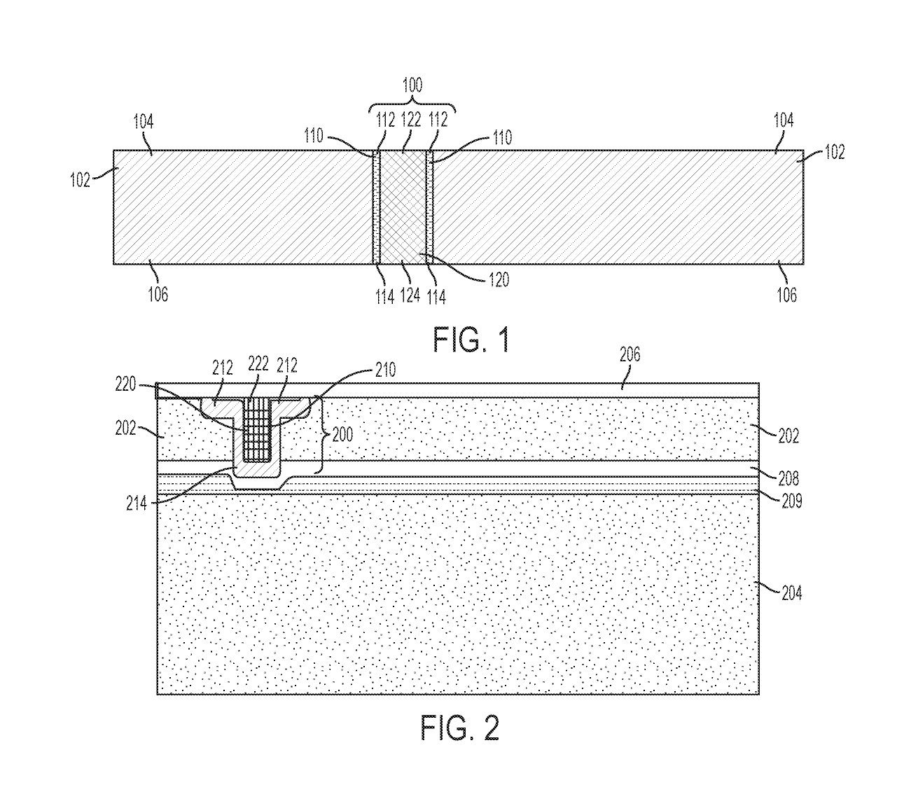

Turning now to a more detailed description of the present invention, FIG. 1 depicts a cross-sectional view of a completed via structure 100 formed in a substrate 102 according to one or more embodiments of the present invention. Substrate 102 includes a front (or top) surface 104 and a back (or bottom) surface 106. Other devices, interconnect layers and conductive vias (not shown) can be formed in or on substrate 102. Via structure 100 includes a conductive liner 110 having a front liner surface 112 and a back liner surface 114. Via structure 100 further includes an insulator fill 120 having a front insulator fill surface 122 and a back insulator fill surface 124. In one or more embodiments, conductive liner 110 is a continuous surface that surrounds portions of insulator fill 120 and forms, in effect, a shell structure around portions of insulator fill 120.

Via structure 100 can be formed by forming (e.g., using reactive ion etching (RIE)) an opening through substrate 102, partially filling (e.g., using a damascene process) the opening with conductive (e.g., superconducting) liner 110, and then filling the remaining space within the opening with insulator fill 120. Via structure 100 is then integrated by making contact to front liner surface 112 and back liner surface 114.

FIG. 2 depicts a cross-sectional view of another completed via structure 200 formed in a first substrate 202 according to one or more embodiments of the present invention. First Substrate 202 and a second substrate 204 form a two-dimensional architecture. Other devices, interconnect layers and conductive vias (not shown) can be formed in or on first and second substrates 202, 204. The two-dimensional architecture also includes a top ground plane 206, a bottom ground plane 208 and an adhesive layer 209 that bonds first substrate 202 (through bottom ground plane 208) to second substrate 204. Via structure 200 includes a conductive liner 210 having a front liner surface 212 and a back liner surface 214. Via structure 200 further includes an insulator fill 220 having a front insulator fill surface 222. In one or more embodiments, conductive liner 210 is a continuous surface that surrounds portions of insulator fill 220 and forms, in effect, a shell structure around portions of insulator fill 220.

Via structure 200 can be formed by forming (e.g., using reactive ion etching (RIE)) an opening through first substrate 202, partially filling (e.g., using a damascene process) the opening with conductive (e.g., superconducting) liner 210, and then filling the remaining space within the opening with insulator fill 220. Via structure 200 is then integrated by making contact to front liner surface 212 and back liner surface 214.

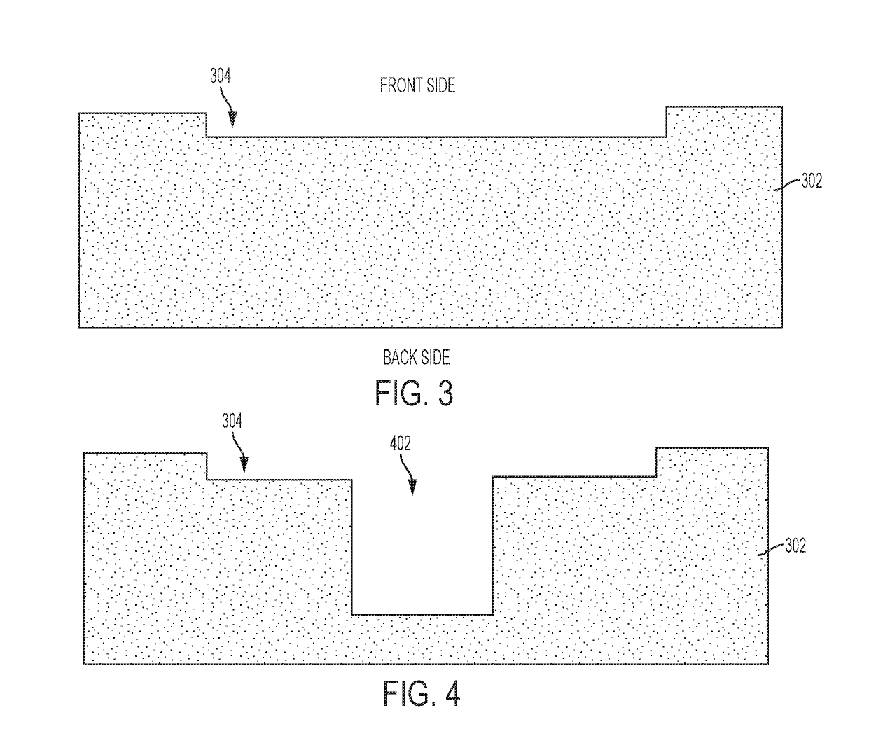

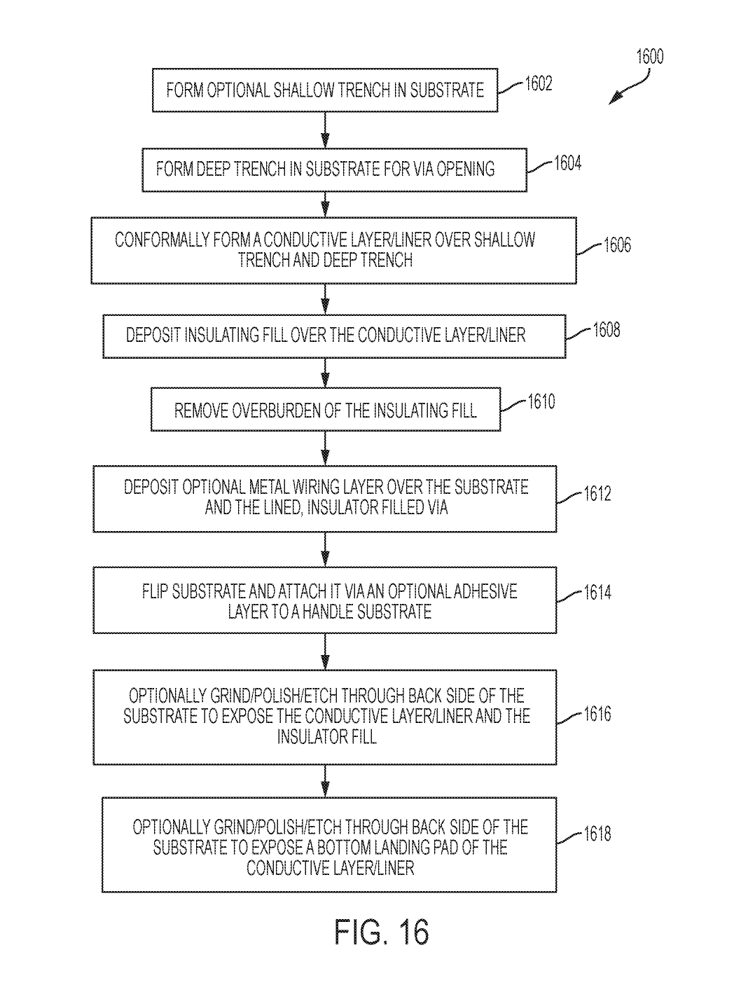

FIGS. 3-15 depict various cross-sectional views of a semiconductor wafer structure after an initial and subsequent via fabrication stages according to one or more embodiments. FIG. 16 depicts a flow diagram illustrating a via fabrication methodology 1600 according to one or more embodiments. A description of via fabrication methodologies according to one or more embodiment of the present invention will now be provided with reference to the initial and subsequent via fabrication stages of the semiconductor wafer structure shown in FIGS. 3-15, as well as methodology 1600 shown in FIG. 16.

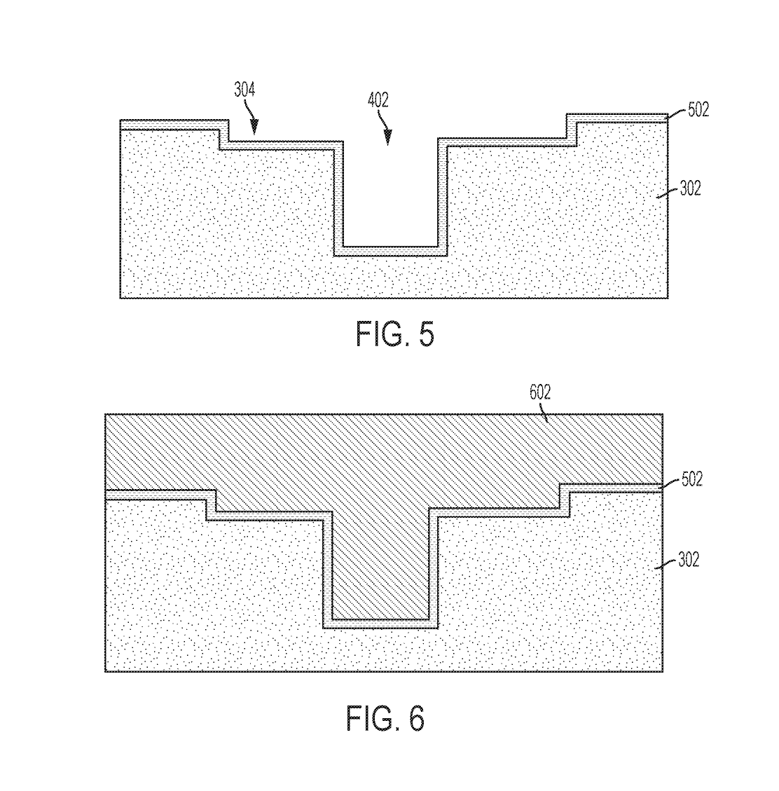

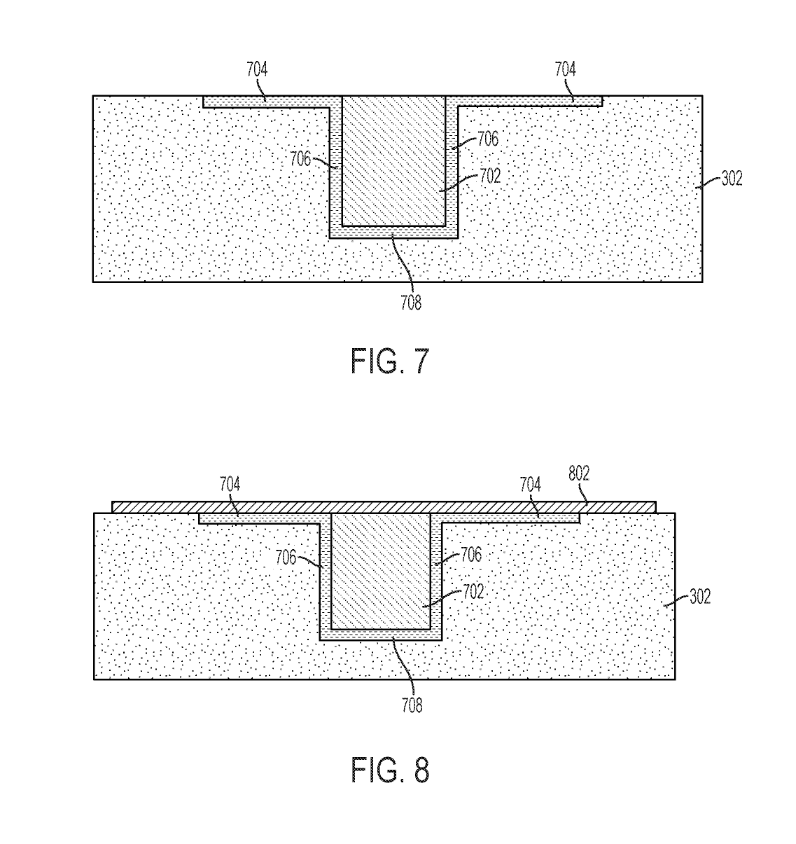

Turning now to FIG. 3, a shallow trench 304 is optionally formed through a front side of a substrate 302 (block 1602). Shallow trench 304 can be formed in a variety of ways, including, for example, reactive ion etching (RIE). Substrate 302 may or may not contain existing features. In one or more embodiments, substrate 302 is a semiconductor. In one or more embodiments, substrate 302 is a silicon wafer. Shallow trench 304 will be used in later fabrication operations to form an optional top landing pad 704 (shown in FIG. 7). In FIG. 4, a deep trench 402 is formed within shallow trench 304 of substrate 302 (block 1604). Deep trench 402 can be formed in a variety of ways, including, for example, RIE. Deep trench 402 will be used in later fabrication operations as the hole or opening of a TSV formed according to embodiments of the present invention. In FIG. 5, a conductive material 502 is conformally deposited over the front side of substrate 302, and more specifically over substrate 302, shallow trench 304 and deep trench 402 (block 1606). In one or more embodiments, conductive material 302 is superconducting material such as TiN, TaN and the like. In one more embodiments, superconducting material is a layer. In one or more embodiments, conductive material 502 within shallow trench region 304 can have a height that is less than the height of shallow trench region 304. In FIG. 6, an insulating material 602 is deposited over conductive layer 502 (block 1608), using, for example a LPCVD (low-pressure chemical vapor deposition) process. In one or more embodiments, an adhesion/protection film (not shown) can be applied to conductive material 502 prior to deposition of insulating material 602. In one or more embodiments, insulating material 602 can be a hard material with a CTE (coefficient of thermal expansion) that is compatible with conductive layer 502 and substrate 302. Insulating material 602 can be a soft material. In one or more embodiments, insulating material 602 can be a polymer-type material such as a photoresist. In one or more embodiments, insulating material 602 can be silicon, TEOS (tetraethyl orthosilicate) oxide and the like.

In FIG. 7, a top portion of insulating material 602 and portions of conductive material 502 are removed (e.g., by a polish or an etch-back operation) such that only an insulating fill 702, a top landing pad conductive material 704, a sidewall liner conductive material 706 and a bottom landing pad conductive material 708 remain over substrate 302 (block 1610). As depicted in FIG. 7, after removal of the top portion of insulating material 602 and portions of conductive material 502, a top surface of substrate 302, a top surface of top landing pad 704 and a top surface of insulating fill 702 are substantially planar with respect to one another. In one or more embodiments, sidewall liner conductive material 706 and bottom landing pad conductive material 708 are continuous surfaces that surround portions of insulator fill 702 and form, in effect, a shell structure around portions of insulator fill 702. For the structure shown in FIG. 7, top landing pad conductive material 704 can be used to provide electrical contact to sidewall liner conductive material 706 and bottom landing pad conductive material 708. Alternatively, as shown in FIG. 8, an optional metal wiring layer 802 can be formed over the top surface of substrate 302, the top surface of top landing pad 704 and the top surface of insulating fill 702 to provide electrical contact through top landing pad conductive material 704 to sidewall liner conductive material 706 and bottom landing pad conductive material 708 (block 1612).

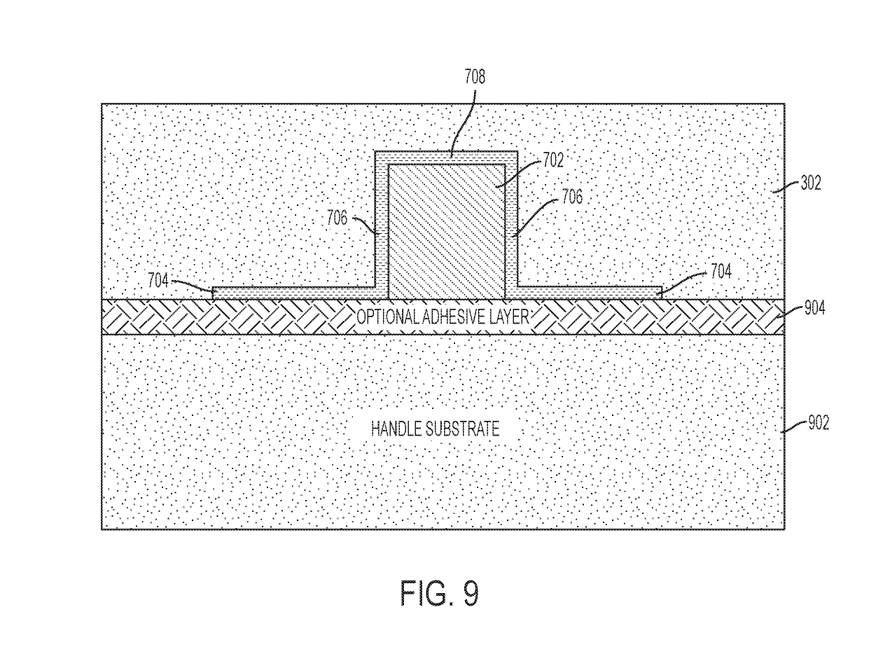

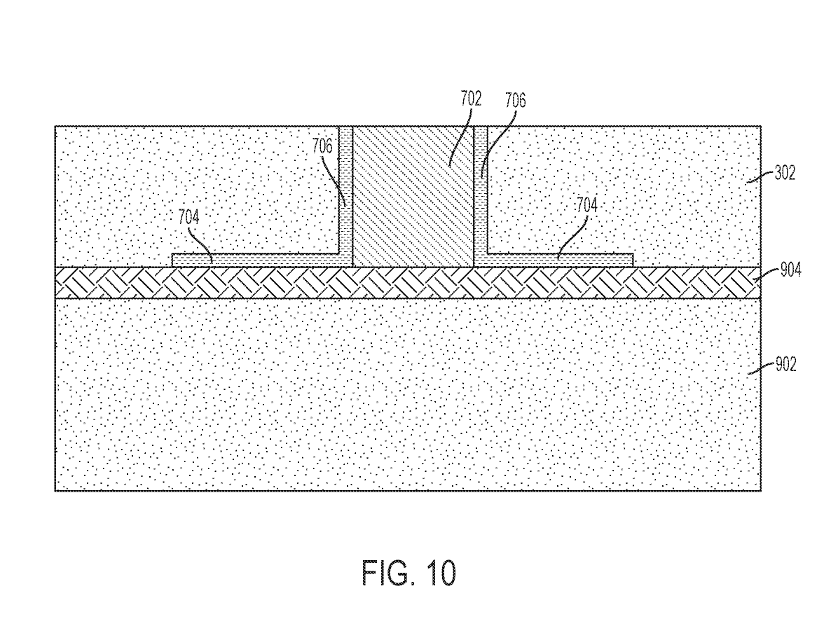

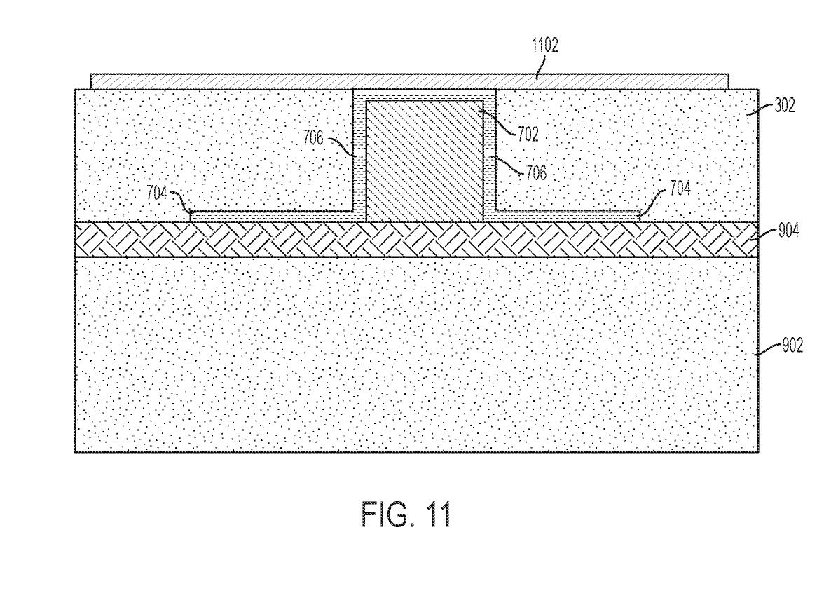

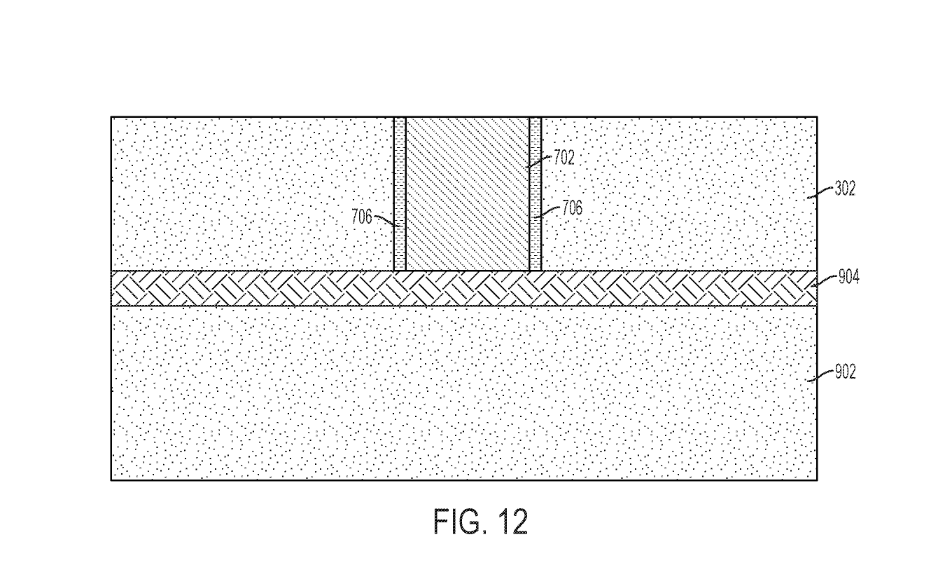

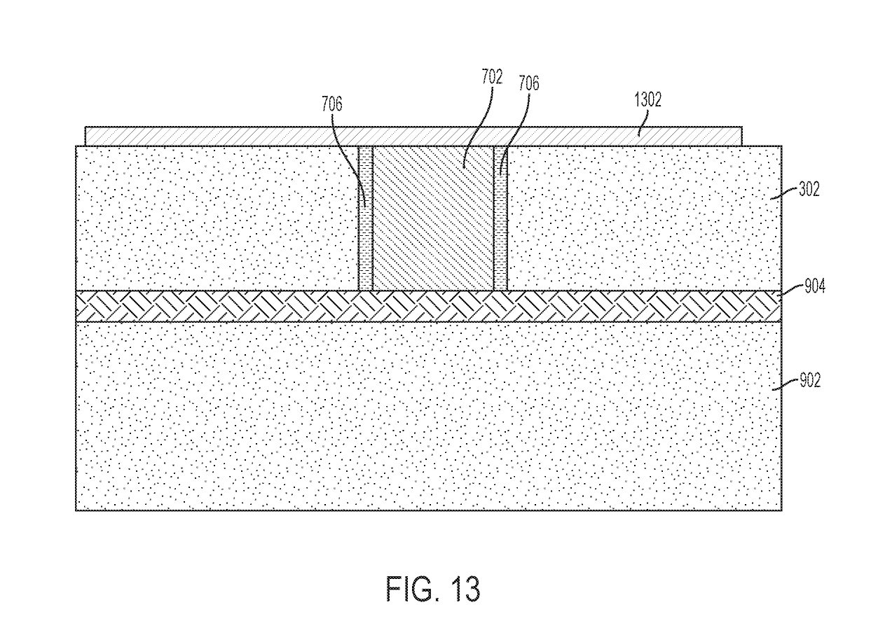

In FIG. 9, substrate 302 is flipped upside down and coupled through an optional adhesive layer 904 to a handle substrate 902, which may or may not be temporary (block 1614). Handle substrate 902 is utilized in order to grind and polish back the back end of substrate 302. In one or more embodiments, substrate 302 is polished back to remove bottom landing pad conductive material 708 as shown in FIG. 10, 11, 12 or 13 (block 1616). FIG. 10 depicts an embodiment wherein bottom landing pad conductive material 708 has be removed and top landing pad conductive material 704 is present. FIG. 11 depicts an embodiment wherein bottom pad conductive material 708 has been removed, the optional top landing pad 704 is present and an optional metal wiring layer 1102 is provided to provide electrical contact through sidewall liner conductive material 706 to top landing pad conductive material 704. FIG. 12 depicts an embodiment wherein bottom pad conductive material 708 has been removed and the optional top landing pad 704 is not present.. FIG. 13 depicts an embodiment wherein bottom pad conductive material 708 has been removed, the optional top landing pad 704 is not present and an optional metal wiring layer 1302 is provided to provide electrical contact through sidewall liner conductive material 706.

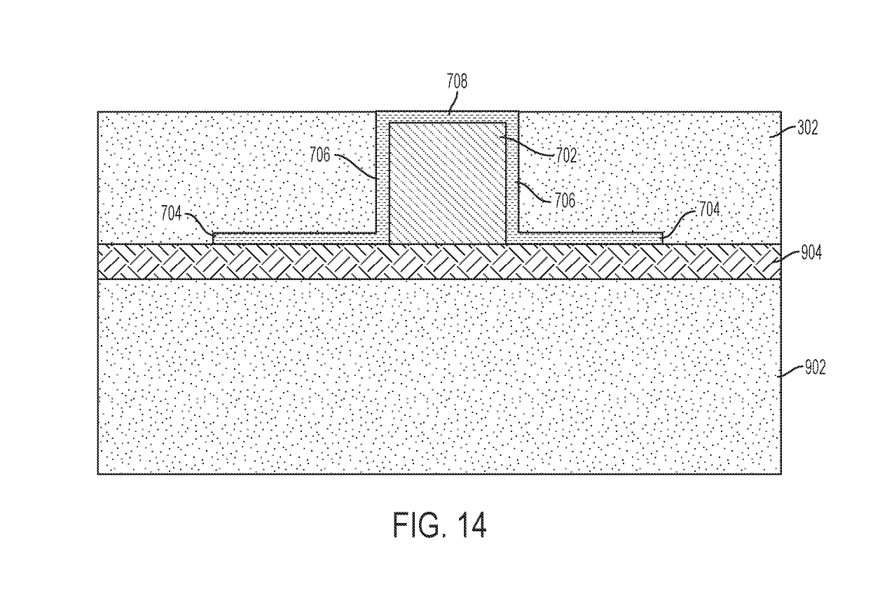

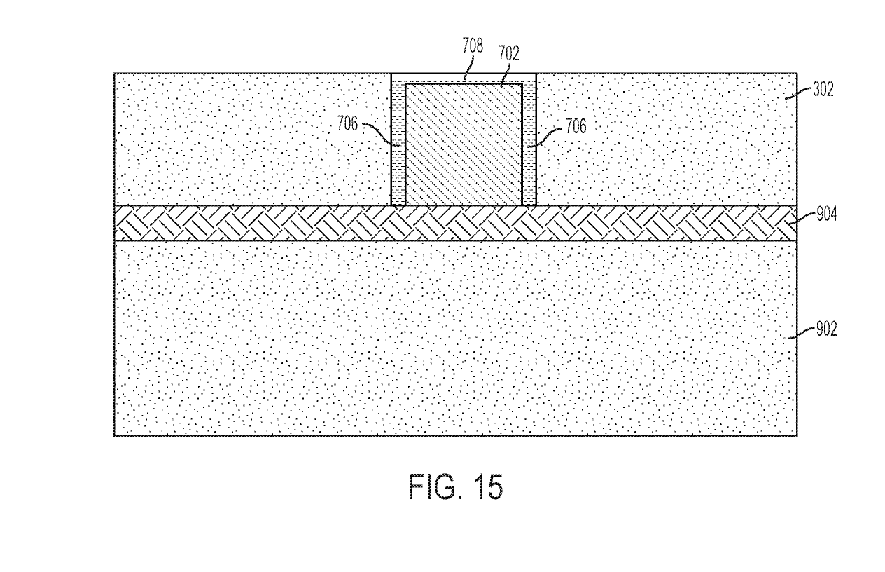

In one or more embodiments, substrate 302 is polished back to reveal bottom landing pad conductive material 708 as shown in FIGS. 14 and 15 (block 1618). FIG. 14 depicts an embodiment wherein bottom pad conductive material 708 has been revealed and the optional top landing pad 704 is present. FIG. 15 depicts an embodiment wherein bottom pad conductive material 708 has been revealed but the optional top landing pad 704 is not present.

Thus, it can be seen from the foregoing detailed description and accompanying illustrations that one or more embodiments of the present invention provide systems, methodologies and resulting structures for forming a conductive via. Technical effects and benefits of the present invention include forming the conducive via as a lined, insulator filled TSV, wherein the lining is formed from conductive material that provides the conduction path of the TSV. In one or more embodiments, the liner is a superconducting material. The disclosed TSV structure can be formed across a range of via aspect ratios, including aspect ratios that would traditionally be considered high (e.g., above about 4:1), as well as aspect ratios that would traditionally be considered low (e.g., between about 2:1 and about 4:1). The conductive liner of the disclosed TSV can be formed with high purity deposition techniques such as PVD. The disclosed TSV structure is substantially coplanar with the front and back surfaces of its host wafer, which facilitates downstream processing that would be compromised by uneven wafer surfaces. The conductive liner and insulating fill of the disclosed TSV sufficiently fill the via opening such that substantially no voids are left in the via after formation of the conductive liner and insulating fill.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The corresponding structures, materials, acts, and equivalents of all means or step plus function elements in the claims below are intended to include any structure, material, or act for performing the function in combination with other claimed elements as specifically claimed. The present invention has been presented for purposes of illustration and description, but is not intended to be exhaustive or limited to the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

The flowchart and block diagrams in the figures illustrate the functionality and operation of possible implementations of systems and methods according to various embodiments of the present invention. In some alternative implementations, the functions noted in the block can occur out of the order noted in the figures. For example, two blocks shown in succession can, in fact, be executed substantially concurrently, or the blocks can sometimes be executed in the reverse order, depending upon the functionality involved. The actions can be performed in a differing order or actions can be added, deleted or modified. Also, the term “coupled” describes having a signal path between two elements and does not imply a direct connection between the elements with no intervening elements/connections therebetween. All of these variations are considered a part of the invention.

The terms “about” or “substantially” are intended to include the degree of error associated with measurement of the particular quantity based upon the equipment available at the time of filing the application. For example, “about” can include a range of ±8% or 5%, or 2% of a given value.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present invention has been described in detail in connection with only a limited number of embodiments, it should be readily understood that the present invention is not limited to such disclosed embodiments. Rather, the present invention can be modified to incorporate any number of variations, alterations, substitutions or equivalent arrangements not heretofore described, but which are commensurate with the spirit and scope of the present invention. Additionally, while various embodiments of the present invention have been described, it is to be understood that aspects of the present invention can include only some of the described embodiments. Accordingly, the present invention is not to be seen as limited by the foregoing description, but is only limited by the scope of the appended claims.

What is claimed is:

1. A method of forming a conductive via, the method comprising:
forming an opening in a substrate;
forming a conductive material along sidewall regions of the opening, wherein the conductive material occupies a first portion of an area within the opening; and
forming an insulating fill in a second portion of the area within the opening;
wherein at least one surface of the conductive material and at least one surface of the insulating fill are substantially coplanar with a front surface of the substrate.

2. The method of claim 1, wherein the conductive material and the insulating fill sufficiently fill the opening such that there are substantially no voids within the opening.

3. The method of claim 1, wherein the conductive material comprises a superconducting material.

4. The method of claim 1, wherein forming the conductive material comprises depositing a layer of the conductive material along the sidewall regions using physical vapor deposition (PVD).

5. The method of claim 1, wherein the at least one surface of the conductive material comprises a top landing pad.

6. The method of claim 1, wherein the opening extends through the substrate from the front surface of the substrate to a back surface of the substrate.

7. The method of claim 6, wherein:
at least one second surface of the conductive material is substantially coplanar with the back surface of the substrate; and
the at least one second surface of the conductive material comprises a bottom landing pad.

8. The method of claim 6, wherein at least one second surface of the conductive material and at least one second surface of the insulating fill are substantially coplanar with the back surface of the substrate.

9. The method of claim 8, wherein an electrical conducting path is provided from the at least one surface of the conductive material to the at least one second surface of the conductive material.

10. A method of forming a conductive via, the method comprising:
forming an opening in a substrate;
forming a layer of superconducting material along sidewall regions of the opening, wherein the layer of superconducting material occupies a first portion of an area within the opening; and
filling a second portion of the area within the opening with an insulating material;
wherein the opening extends through the substrate from a front surface of the substrate to a back surface of the substrate;
wherein at least one surface of the layer of superconducting material and at least one surface of the insulating fill are substantially coplanar with the front surface of the substrate;
wherein at least one second surface of the layer of superconducting material is substantially coplanar with the back surface of the substrate;
wherein an electrical conducting path is provided from the at least one surface of the layer of superconducting material to the at least one second surface of the layer of superconducting material.

11. The method of claim 10, wherein the at least one surface of the layer of superconducting material comprises a top landing pad.

12. The method of claim 10, wherein the at least one second surface of the layer of superconducting material comprises a bottom landing pad.

13. The method of claim 10, wherein the at least one second surface of the layer of superconducting material and at least one second surface of the insulating fill are substantially coplanar with the back surface of the substrate.

14. The method of claim 10 further comprising forming the layer of superconducting material using a physical vapor deposition (PVD) process.

15. A conductive via comprising:
an opening in a substrate;
a conductive material along sidewall regions of the opening, wherein the conductive material occupies a first portion of an area within the opening; and
an insulating fill in a second portion of the area within the opening;
wherein at least one surface of the conductive material and at least one surface of the insulating fill are substantially coplanar with a front surface of the substrate.

16. The via of claim 15, wherein the conductive material and the insulating fill sufficiently fill the opening such that there are substantially no voids within the opening.

17. The via of claim 15, wherein the conductive material comprises a superconducting material.

18. The via of claim 15, wherein the at least one surface of the conductive material comprises a top landing pad.

19. The via of claim 15, wherein:
the opening extends through the substrate from the front surface of the substrate to a back surface of the substrate;
at least one second surface of the conductive material is substantially coplanar with the back surface of the substrate; and
the at least one second surface of the conductive material comprises a bottom landing pad.

20. The via of claim 15, wherein:
at least one second surface of the conductive material and at least one second surface of the insulating fill are substantially coplanar with a back surface of the substrate; and
an electrical conducting path is provided from the at least one surface of the conductive material to the at least one second surface of the conductive material.
